(19) United States
(12) Patent Application Publication
(10) Pub. No.: US 2026/0371892 A1
(43) Pub. Date: Nov. 19, 2026

(54) DISPLAY DEVICE AND DISPLAY METHOD

(71) Applicants: Chengdu BOE Optoelectronics Technology Co., Ltd., Chengdu, Sichuan (CN); BOE Technology Group Co., Ltd., Beijing (CN)

(72) Inventor: Dezhao MA, Beijing (CN)

(21) Appl. No.: 18/996,011

(22) PCT Filed: Aug. 13, 2024
(86) PCT No.: PCT/CN2024/111616

§ 371 Date: Jan. 17, 2025

(30) Foreign Application Priority Data
Sep. 11, 2023 (CN) 202311167771.5

(51) Int. Cl. H10K 59/50; G02F 1/157; G02F 1/163; H10K 59/126; H10K 59/38; H10K 59/80

(52) U.S. Cl. CPC H10K 59/50; G02F 1/157; G02F 1/163; H10K 59/126; H10K 59/38; H10K 59/8792

(57) ABSTRACT

The present application discloses a display device and display methods, where the display device including: a light-emitting layer and a light-shielding layer, the light-emitting layer being disposed opposite the light-shielding layer; the light-emitting layer including a number of sub-pixel light-emitting regions, and the light-shielding layer including a number of first light-shielding members; each of the sub-pixel light-emitting regions corresponds to at least one first light-shielding member, where the first light-shielding members corresponding to each of the sub-pixel light-emitting regions are disposed around a target side of the sub-pixel light-emitting region to block light emitted from the sub-pixel light-emitting region on the target side. This can avoid affecting a driver's line of sight and at the same time not affecting an overall display brightness of the display device as much as possible.

### CROSS REFERENCE TO RELATED APPLICATIONS

The present application is a U.S. National Stage of International Application No. PCT/CN2024/111616 filed on Aug. 13, 2024 which claims the priority benefit of Chinese Patent Application No. 202311167771.5 filed on Sep. 11, 2023, and the content of which is incorporated herein by reference in its entirety.

### TECHNICAL FIELD

The present application relates to display technology, and in particular to a display device and display methods.

### BACKGROUND

A display device is a device used for displaying images and colors, and is widely used in cell phones, computers, monitors, televisions, and other devices with image or text display functions.

Take the display device as a vehicle display screen as an example, with gradually increased market demands for expansion of screen functions in a scenario involving a vehicle display screen, a size of the vehicle display screen is also becoming larger and screen brightness of the vehicle display screen is also increasing. However, in a process of vehicle driving, light emitted from a large-sized screen has a larger light emission angle, screen light coverage is also wider, and even the screen light can shine on a vehicle windshield, which will interfere with a driver's field of vision and affect driving safety.

### SUMMARY

In response to above technical problems, the present application provides a display device and display methods, with technical solutions as follows.

According to a first aspect of the present application, there is provided a display device including: a light-emitting layer and a light-shielding layer, the light-emitting layer being disposed opposite the light-shielding layer;
the light-emitting layer includes a number of sub-pixel light-emitting regions, and the light-shielding layer includes a number of first light-shielding members; each of the sub-pixel light-emitting regions corresponds to at least one first light-shielding member, where the first light-shielding members corresponding to each of the sub-pixel light-emitting regions are disposed around a target side of the sub-pixel light-emitting region to shield light emitted from the sub-pixel light-emitting region on the target side.

In an example, the display device is applied to a vehicle driving scenario, and the display device includes at least a main driver display region; within the main driver display region, the target side includes a side of the sub-pixel light-emitting region near a vehicle windshield.

In an example, the display device is applied to a vehicle driving scenario, and the display device includes at least a front-seat passenger display region; within the front-seat passenger display region, the target side comprises a side of the sub-pixel light-emitting region near a vehicle windshield, and/or, the target side comprises a side of the sub-pixel light-emitting region near a main driver's seat.

In an example, the display device is applied to a vehicle driving scenario, and the display device includes at least a center control display region; within the center control display region, the target side is a side of the sub-pixel light-emitting region near a vehicle windshield.

In an example, the display device is applied to a vehicle driving scenario, and the display device integrates a main driver display region, a front-seat passenger display region, and a center control display region; within the main driver display region, the target side includes a side of the sub-pixel light-emitting region near a vehicle windshield; within the front-seat passenger display region, the target side includes a side of the sub-pixel light-emitting region near the vehicle windshield, and/or, the target side includes a side of the sub-pixel light-emitting region near a main driver's seat; and within the center control display region, the target side includes the side of the sub-pixel light-emitting region near the vehicle windshield.

In an example, the first light-shielding member is an electrochromic material, the electrochromic material being capable of changing to different colors when different voltages are applied.

In an example, the electrochromic material is capable of changing to black when no voltage is applied; and the electrochromic material is capable of changing to a same color as a sub-pixel color when a target voltage is applied.

In an example, the first light-shielding member is a black matrix.

In an example, the display device further includes a light filtering layer, the light filtering layer being disposed between the light-emitting layer as well as the light-shielding layer, and for cooperating with the light-emitting layer to absorb ambient light emitted into the display device.

In an example, the light filtering layer includes a COE structure.

In an example, the light filtering layer includes a number of light-transmitting regions and a number of second light-shielding members; each of the sub-pixel light-emitting regions corresponds to one of the light-transmitting regions, the light-transmitting region being used for transmitting light emitted from the sub-pixel light-emitting region; the second light-shielding member is an electrochromic material, the electrochromic material being capable of changing to different colors when different voltages are applied; the second light-shielding member is disposed in the light-transmitting region and around the target side.

In an example, a number and/or thickness of the first light-shielding members corresponding to each of the sub-pixel light-emitting regions is determined according to a size of an area of the sub-pixel light-emitting region.

In an example, a shape of the first light-shielding member corresponds to an edge shape of the corresponding sub-pixel light-emitting region.

According to a second aspect of the present application, there is provided a display method, the display method being applied to the display device as described in the first aspect, where the first light-shielding member is an electrochromic material, the electrochromic material being capable of changing to different colors when different voltages are applied, the method including:
determining a sub-pixel color corresponding to the sub-pixel light-emitting region; and
applying a target voltage to the electrochromic material based on the sub-pixel color to cause a color of the electrochromic material to change to the sub-pixel color.

According to a third aspect of the present application, there is provided a display method, the display method being applied to the display device as described in the first aspect, where the first light-shielding member and/or the second light-shielding member is the electrochromic material, the method including:
determining a sub-pixel color corresponding to the sub-pixel light-emitting region; and
applying a target voltage to the electrochromic material based on the sub-pixel color, to cause a color of the electrochromic material to change to the sub-pixel color.

The technical solution provided by embodiments of the present application is capable of providing a light-shielding member on one side of the sub-pixel light-emitting region in the display device as needed to shield the large-angle light emitted from the sub-pixel light-emitting region on that side to avoid affecting the driver's line of sight, and at the same time to ensure that the light emitted from the sub-pixel light-emitting region on the other side is normal, so as to minimize affecting the overall display brightness of the display device.

It should be understood that the above general description and the detailed description that follows are exemplary and explanatory only and do not limit the present application.

### BRIEF DESCRIPTION OF DRAWINGS

In order to more clearly illustrate the technical solutions in the embodiments of the present application or the related technology, the following will briefly introduce the accompanying drawings to be used in the description of the embodiments or the related technology. It will be apparent that the accompanying drawings in the following description are only some of the embodiments documented in the present application, and that for a person of ordinary skill in the field, other accompanying drawings can be obtained based on these drawings.

FIG. 1 is a schematic diagram of a light-emitting scenario of screen sub-pixel in a related technology.

FIG. 2 is a schematic diagram of another light-emitting scenario of screen sub-pixel in a related technology.

FIG. 3 is a schematic structural diagram of a display device of an embodiment of the present application.

FIG. 4 is a schematic structural diagram of a display device of another embodiment of the present application.

FIG. 5 is a schematic structural diagram of a display device of another embodiment of the present application.

FIG. 6 is a schematic structural diagram of a display device of another embodiment of the present application.

FIG. 7 is a schematic structural diagram of a display device of another embodiment of the present application.

FIG. 8 is a schematic structural diagram of a display device of another embodiment of the present application.

FIG. 9 is a schematic diagram of correspondence between a shape of a sub-pixel and a shape of a light-shielding member of an embodiment of the present application.

FIG. 10 is a schematic diagram of an application scenario of a display device of an embodiment of the present application.

FIG. 11 is a schematic diagram of an application scenario of a display device of another embodiment of the present application.

FIG. 12 is a schematic diagram of an application scenario of a display device of another embodiment of the present application.

FIG. 13 is a schematic flow diagram of a display method of an embodiment of the present application.

FIG. 14 is a schematic flow diagram of a display method of another embodiment of the present application.

### DETAILED DESCRIPTION

In order to enable those skilled in the art to better understand the technical solutions in the present application, the technical solutions in the embodiments of the present application will be described in detail below in conjunction with the accompanying drawings in the embodiments of the present application. It is apparent that the described embodiments are only a part of the embodiments of the present application, but not all of the embodiments. Based on the embodiments in this application, all other embodiments obtained by a person of ordinary skill in the art shall fall within the scope of protection of this application.

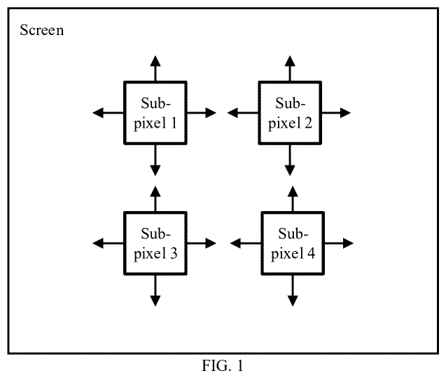

Referring to FIG. 1, take a display device as a screen as an example, a screen sub-pixel light-emitting scenario is first exemplarily introduced, where a screen is a device for displaying images and colors, and is widely used in cell phones, computers, monitors, televisions, and other devices with image or text display functions.

Take the display device as a vehicle display screen as an example, with gradually increased market demands for expansion of screen functions in a scenario involving a vehicle display screen, a size of the vehicle display screen is also becoming larger and screen brightness of the vehicle display screen is also increasing. However, in a process of vehicle driving, light emitted from a large-sized screen has a larger light emission angle, screen light coverage is also wider, and even the screen light can shine on a windshield of the vehicle, which will interfere with a driver's field of vision and affect driving safety.

Taking FIG. 1 as an example, it is assumed that there are four sub-pixels (sub-pixel 1, sub-pixel 2, sub-pixel 3, and sub-pixel 4) on the screen. Light emitted from light-emitting regions of these four sub-pixels can cover multiple directions (not limited to directions indicated by four arrows in the light-emitting region of a single sub-pixel as shown in FIG. 1).

In a vehicle display scenario, for example, light emitted from the sub-pixel light-emitting regions at a large-angle, such as light emitted in an upward direction with respect to a driver (as indicated by upward arrows on each of the sub-pixel light-emitting regions in FIG. 1), may shine on a vehicle windshield, affecting the driver's field of vision.

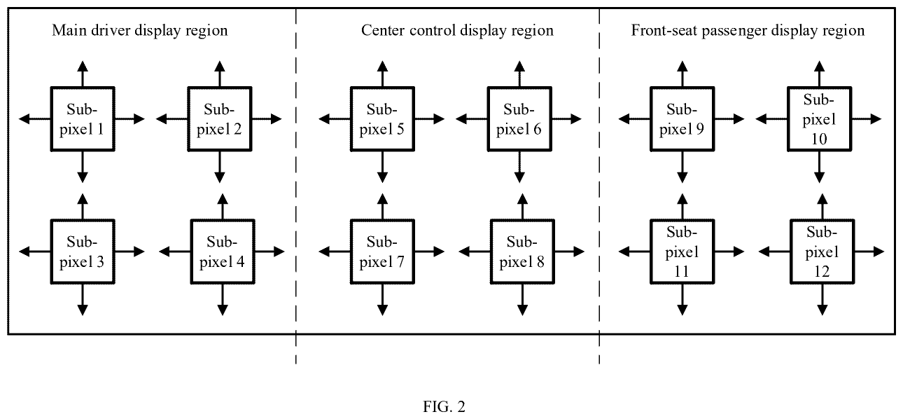

Taking FIG. 2 as an example, in the related technology, in the vehicle display scenario, there exists a situation in which a main driver screen (e.g., dashboard screen), a center control screen, and a front-seat passenger screen are integrated in a same in-vehicle screen such as a screen in FIG. 2. It is assumed that there exist four sub-pixels (sub-pixel 1, sub-pixel 2, sub-pixel 3, and sub-pixel 4) on the main driver screen region, four sub-pixels (sub-pixel 5, sub-pixel 6, sub-pixel 7, and sub-pixel 8) on the center control screen region, and four sub-pixels (sub-pixel 9, sub-pixel 10, sub-pixel 11, and sub-pixel 12) on the front-seat passenger screen region. The situation described with reference to FIG. 1, i.e., a large-angle light emitted from the sub-pixel light-emitting region shining on a vehicle windshield, is present in the main driver screen region, the center control screen region, and the front-seat passenger screen region. In addition, in the front-seat passenger screen region, because that a front-seat passenger often uses the front-seat passenger screen due to entertainment needs, the front-seat passenger screen is often able to provide a wide range of entertainment functions. This leads to that the brightness of display of the front-seat passenger screen is often higher, and content displayed on the front-seat passenger screen often changes significantly in a unit of time, so that screen color and the brightness also changes rapidly in a unit of time in response to the change of the displayed content. Then a large-angle light emitted from the front-seat passenger screen region in a direction of facing a main driver is often easier to affect the main driver's line of sight (e.g., a large-angle light emitted from each sub-pixel light-emitting region of the front-seat passenger screen region in a direction indicated by the left-side arrows in FIG. 2).

It can be understood that in actual application scenarios, the number of sub-pixels contained in a screen is much larger than the number of sub-pixels shown in FIG. 1 as well as FIG. 2, and there are many variations in an arrangement of all sub-pixels without being limited to those shown in FIGS. 1 to 2. Thus, there is no specific limitation on the number and the arrangement of sub-pixels.

In the related technology, Black Matrix (BM) material is used to stack around each sub-pixel light-emitting region of the screen in order to block a large-angle light emitted from each sub-pixel light-emitting region. However, the blocking of the large-angle light from the sub-pixel light-emitting regions in all directions will significantly affect the brightness of the screen display, resulting in a poor visual effect of the screen.

It is worth stating that the above introduction of a light-emitting scenario of the screen sub-pixel with the screen as an example of the display device is only an exemplary demonstration. In practical application, other application scenarios are not excluded, and the display device is not limited to the screen, which is not limited specifically.

In response to the above problems, the present application provides a display device that is capable of avoiding influence on the driver's line of sight while not affecting an overall display brightness of the display device as much as possible.

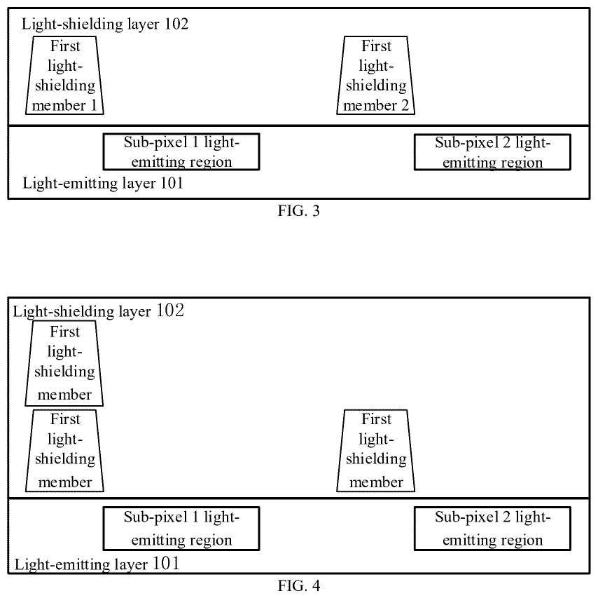

As shown in FIG. 3, the display device may include a light-emitting layer 101 as well as a light-shielding layer 102, and the light-emitting layer 101 and the light-shielding layer 102 may be disposed opposite each other.

The light-emitting layer 101 includes a number of sub-pixel light-emitting regions (e.g., sub-pixel 1 light-emitting region and sub-pixel 2 light-emitting region in FIG. 3), and the light-shielding layer 102 includes a number of first light-shielding members (e.g., the first light-shielding member 1 and the first light-shielding member 2 shown in FIG. 3). Each of the sub-pixel light-emitting regions corresponds to at least one of the first light-shielding members (e.g., sub-pixel 1 light-emitting region may correspond to the first light-shielding member 1, and the sub-pixel 2 light-emitting region may correspond to the first light-shielding member 2), where the first light-shielding member corresponding to each sub-pixel light-emitting region is disposed around a target side of the sub-pixel light-emitting region to block the light emitted from the sub-pixel light-emitting region on the target side.

As shown in FIG. 4, a number of first light-shielding members corresponding to each sub-pixel light-emitting region may be one, two, three or more. In FIG. 4, for example, the sub-pixel 1 light-emitting region may correspond to two first light-shielding members, the sub-pixel 2 light-emitting region may correspond to one first light-shielding member, and the number of first light-shielding members corresponding to each sub-pixel light-emitting region may be the same or different. Thus, the number of first light-shielding members corresponding to each sub-pixel light-emitting region is not limited specifically.

When there are a plurality of first light-shielding members corresponding to the sub-pixel light-emitting region, the plurality of first light-shielding members may be arranged in a plurality of ways, and as an example, one of the arrangements may include: the plurality of first light-shielding members may be sequentially stacked in a direction perpendicular to the display device at a certain spacing. For example, as shown in FIG. 4, two first light-shielding members corresponding to the sub-pixel 1 light-emitting region are stacked in a direction perpendicular to the light-emitting layer 101 and the light-shielding layer 102 (i.e., perpendicular to the display device) at a certain spacing. It is worth noting that the above description of the arrangement of the first light-shielding members is only an exemplary demonstration, and in practical application, other arrangement methods are not excluded, which is not limited specifically.

Taking a driving scenario as an example, the aforementioned display device can be applied to a vehicle driving scenario. The display device includes at least a main driver display region, which shows content that a driver needs to know during a driving process and is related to vehicle driving, such as dashboard displays, vehicle status displays, and other similar content. Within the main driver display region, a first light-shielding member corresponding to each sub-pixel light-emitting region is provided around the above-described target side, i.e., a side of the sub-pixel light-emitting region close to the vehicle windshield, so as to block the light emitted from the sub-pixel light-emitting region on the side close to the vehicle windshield. The light emitted from the display device in the direction of the vehicle windshield can be blocked in the main driver screen region of the display device, and reflection of the light emitted from the main driver screen region in the direction of the vehicle windshield can be avoided so as to avoid affecting vision of a driver.

Taking the driving scenario as an example, the above-described display device may be applied to the vehicle driving scenario. The display device may at least include a center control display region. Content displayed in the center control display region may be content related to controlling software or hardware devices in the vehicle, such as an in-vehicle air-conditioning control interface, an in-vehicle music control interface, and the like. Within the center control display region, a first light-shielding member corresponding to each sub-pixel light-emitting region is provided around the target side, i.e., the side of such sub-pixel light-emitting region close to the vehicle windshield, so as to block the light emitted from such sub-pixel light-emitting region on the side close to the vehicle windshield. The light emitted from the center control display region of the display device in the direction of the vehicle windshield can be blocked in the center control display region of the display device, and reflection of the light emitted from the center control display region in the direction of the vehicle windshield can be avoided so as to avoid affecting vision of a driver.

Taking FIG. 5 as an example, it is illustrated that for the above-mentioned main driver display region as well as the center control display region, as shown in FIG. 5, since the vehicle windshield is often positioned above the display device, the above-mentioned first light-shielding members may be provided around an upper side of the respective sub-pixel light-emitting regions of the display device to shield the light emitted by the sub-pixel light-emitting regions at the upper side.

Taking the driving scenario as an example, the above-described display device may be applied to the vehicle driving scenario, and the display device may at least include a front-seat passenger display region, and the content displayed in the front-seat passenger display region may be content displayed to satisfy various needs of a front-seat passenger, for example, multimedia content for entertainment, such as information on playing music, videos, games, and other entertainment content. Within the front-seat passenger display region, the first light-shielding member corresponding to each sub-pixel light-emitting region may be provided around the side of the sub-pixel light-emitting region near the vehicle windshield to block the light emitted from the sub-pixel light-emitting region on the side near the vehicle windshield. The first light-shielding member corresponding to each sub-pixel light-emitting region may also be provided around the side of the sub-pixel light-emitting region near a main driver's seat to block the light emitted from the sub-pixel light-emitting region on the side near the main driver's seat. The light emitted from the display device in the direction of the vehicle windshield and in the direction of the main driver's seat can be blocked in the front-seat passenger display region of the display device to avoid affecting the driver's line of sight.

It is to be understood that for the above front-seat passenger display region, the first light-shielding member may be provided around the side of the sub-pixel light-emitting region near the vehicle windshield, or may be provided only around the side of the sub-pixel light-emitting region near the main driver's seat, and may be provided around both the side of the sub-pixel light-emitting region near the vehicle windshield as well as the side of the sub-pixel light-emitting region near the main driver's seat, which is not limited specifically.

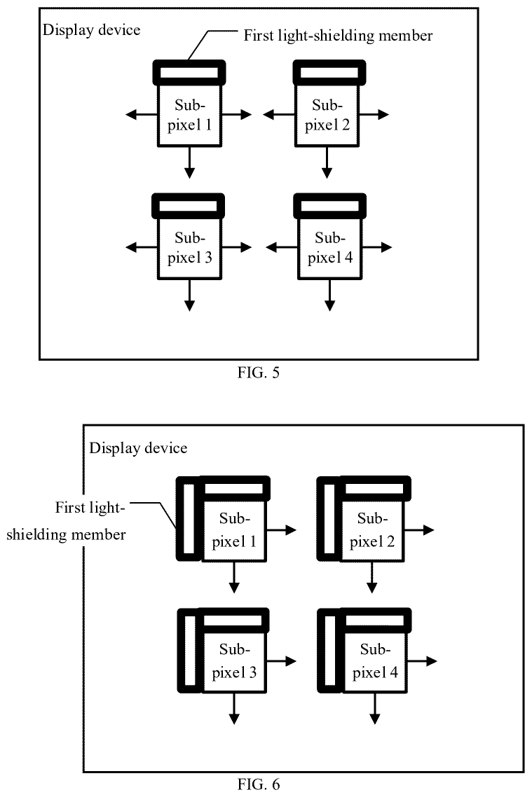

Taking FIG. 6 as an example for illustration: for the above front-seat passenger display region, as shown in FIG. 6, since the vehicle windshield is often positioned above the display device, and the main driver's seat is often on the left (e.g., in a left-hand drive vehicle) or on the right (e.g., in a right-hand drive vehicle) of the front-seat passenger display region, the above-described first light-shielding members may be provided around the upper side of the respective sub-pixel light-emitting regions of the display device, and may also be provided around the left side or the right side of the respective sub-pixel light-emitting regions of the display device, so as to block the light emitted from the sub-pixel light-emitting regions on the upper side or the left side or the right side.

Taking the driving scenario as an example, the above display device can be applied to the vehicle driving scenario, and the display device can be integrated with the main driver display region, the front-seat passenger display region, and the center control display region. The content displayed in the main driver display region can be the content that the driver needs to know during the driving process and is related to vehicle driving, such as the dashboard displays, vehicle status displays, and other similar content. In the main driver display region, the first light-shielding member corresponding to each sub-pixel light-emitting region is provided around the above-described target side. The content displayed in the front-seat passenger display region may be content displayed to satisfy the various needs of a front-seat passenger, for example, multimedia content for entertainment, such as information on playing music, videos, games, and other entertainment content. Within the front-seat passenger display region, the first light-shielding member corresponding to each sub-pixel light-emitting region may be provided around the side of the sub-pixel light-emitting region near the vehicle windshield. The first light-shielding member corresponding to each sub-pixel light-emitting region may be provided around the side of the sub-pixel light-emitting region near the main driver's seat. It is to be understood that, for the above-described front-seat passenger display region, the first light-shielding member may be provided around the side of the sub-pixel light-emitting region near the vehicle windshield, or may be provided around the side of the sub-pixel light-emitting region near the main driver's seat only, or may be provided around both the side of the sub-pixel light-emitting region near the vehicle windshield and the side of the sub-pixel light-emitting region near the main driver's seat, which is not limited specifically. The content displayed in the center control display region may be content related to controlling software or hardware devices in the vehicle, such as an in-vehicle air-conditioning control interface, an in-vehicle music control interface, and the like. Within the center control display region, the first light-shielding member corresponding to each sub-pixel light-emitting region is provided around the above-described target side, i.e., the side of the sub-pixel light-emitting region near the vehicle windshield. With the development of a display device integrating a plurality of different types of display regions, for example, in a case of a triple screen in which the main driver display, the center control display, and the front-seat passenger display are integrated, it is possible to carry out a light-shielding design for each different type of display region separately, so as to make the arrangement of the light-shielding member associated with the type of display region.

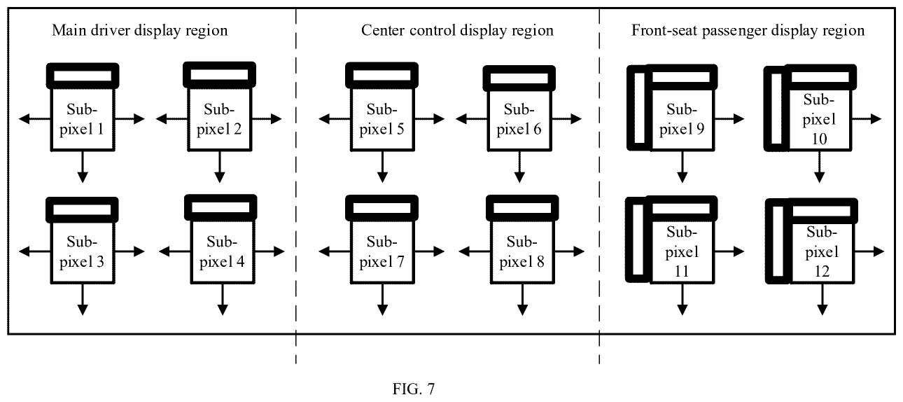

Take FIG. 7 as an example: in a case where the display device is integrated with the main driver display region, the front-seat passenger display region and the center control display region, as shown in FIG. 7, since the vehicle windshield is often positioned above the display device, and the main driver's seat is often on the left (e.g., for left-hand drive vehicles) or on the right (e.g., for right-hand drive vehicles) of the front-seat passenger display region, the first light-shielding members may be provided around the upper side of the respective sub-pixel light-emitting regions of the display device to block the light emitted from the sub-pixel light-emitting regions on the upper side. For the front-seat passenger display region, the above-described first light-shielding members may be provided around the upper side of the respective sub-pixel light-emitting regions of the display device, and may be provided around the left or right side of the respective sub-pixel light-emitting regions of the display device to block the light emitted from the sub-pixel light-emitting regions on the upper side or on the left or right side.

It is worth stating that the above description of the light-shielding member arrangement of the different types of display regions of the display device is only an exemplary demonstration, and in practical application, other types of display regions and light-shielding member arrangement are not excluded, which is not limited specifically.

There are various specific implementations of the first light-shielding member, and as an example, one of the implementations may include: the first light-shielding member may adopt an electrochromic material, which is capable of changing to different colors when different voltages are applied. Changing to different colors at different voltages can satisfy a need for light shielding in different scenarios.

There are various ways in which the above-described electrochromic material changes color in response to a change in voltage, and as an example, one of the implementations may include: the above-described electrochromic material is capable of changing to black when no voltage is applied, and the above-described electrochromic material is capable of changing to a color that is the same as a sub-pixel color when a target voltage is applied. For example: taking the vehicle driving scenario as an example, during driving, if no voltage is applied to the above-mentioned electrochromic material, the color of the electrochromic material is black, which can absorb light emitted from the sub-pixel light-emitting region to the electrochromic material, so as to achieve the light-shielding effect. And when the vehicle is parked, if a target voltage is applied to the electrochromic material, the electrochromic material is able to change to the same color as the sub-pixel color. For example, if the sub-pixel is red, the electrochromic material can change to red under the target voltage, and if the sub-pixel is blue, the electrochromic material can change to blue under the target voltage. Sub-pixels of different colors can correspond to different target voltages, and when the electrochromic material changes to the same color as the sub-pixel, the light emitted from the sub-pixel light-emitting region to the electrochromic material can be transmitted through the electrochromic material. The presence of the electrochromic material can ensure that the light emitted by the display device does not affect the driver's line of sight during the driving process of the vehicle to ensure safe driving, and to ensure the brightness of display of the display device during the parking process to avoid excessive power consumption.

It is worth stating that the above description of the color change mode of the electrochromic material is only an exemplary demonstration, and other change modes are not ruled out in practical applications, which is not limited specifically.

As an example, another implementation of the first light-shielding member may include that the first light-shielding member may be Black Matrix. It is worth stating that the above description of the specific realization of the first light-shielding member is only an exemplary demonstration, and other specific realizations are not ruled out in practical applications, for which no limitation is made.

As shown in FIG. 8, the above display device may also include a light filtering layer 103, the light filtering layer 103 is disposed between the light-emitting layer 101 and the light-shielding layer 102, and the light filtering layer 103 may be used to cooperate with the light-emitting layer 101 to absorb ambient light incident to the display device. There is often ambient light incident to the inside of the display device from the outside, and the reflected light of the ambient light at the display device, if not processed, will significantly affect the display effect of the display device and reduce the user experience. By the filtering layer cooperating with and the light-emitting layer, the incident ambient light is absorbed as much as possible to reduce the reflection of the ambient light, and the display effect of the display device can be improved.

A structure of the light filtering layer 103 may be implemented in a variety of specific ways, and as an example, one such implementation may include that the light filtering layer 103 may be a Color filter On Encapsulation (COE) structure.

For an exemplary illustration of the above COE structure: the COE structure includes a number of black matrices and light-transmitting regions respectively corresponding to the sub-pixel light-emitting regions, where the light-transmitting region may be a Color Filter (CF), and each CF is surrounded by the black matrices.

It is worth stating that the above description of the specific implementation of the structure of the light filtering layer 103 is only an exemplary demonstration, and other specific realizations are not ruled out in practical applications, for which no limitation is made.

As shown in FIG. 8, as an example, another implementation of the structure of the light filtering layer 103 may include: the light filtering layer 103 includes a number of light-transmitting regions and a number of second light-shielding members; each sub-pixel light-emitting region of the light-emitting layer 101 may correspond to one of the above-mentioned light-transmitting regions, where the light-transmitting region is used for transmitting light emitted from the corresponding sub-pixel light-emitting region; the above-mentioned second light-shielding member may adopt an electrochromatic material which can change to different colors when different voltages are applied; the above-mentioned second light-shielding member may be disposed in the above-mentioned light-transmitting region and is disposed around a target side of the sub-pixel light-emitting region corresponding to the light-transmitting region. The above-described electrochromic material is capable of changing to a black color when no voltage is applied, and the above-described electrochromic material is capable of changing to the same color as the sub-pixel color when a target voltage is applied. For example: taking the vehicle driving scenario as an example, during driving, if no voltage is applied to the above electrochromic material, the color of the electrochromic material is black, so as to absorb the light emitted from the sub-pixel light-emitting region to the electrochromic material, thereby achieving the light-shielding effect; and when the vehicle is parked, if a target voltage is applied to the electrochromic material, it is able to change to the same color as the sub-pixel color. For example, if the sub-pixel is red, the electrochromic material can change to red under the target voltage, and if the sub-pixel is blue, the electrochromic material can change to blue under the target voltage, and sub-pixels of different colors can correspond to different target voltages. When the electrochromic material changes to the same color as the sub-pixel, the light emitted from the sub-pixel light-emitting region to the electrochromic material can be transmitted through the electrochromic material. The presence of the electrochromic material can ensure that the light emitted by the display device does not affect the driver's line of sight during the driving process of the vehicle to ensure safe driving, and to ensure the brightness of display of the display device during the parking process to avoid excessive power consumption.

It is understood that when the above-described display device includes the light filtering layer 103, the above-described first light-shielding member and the above-described second light-shielding member may be provided in the above-described display device at the same time, or one of the two may be provided separately, and both ways are capable of realizing the light-shielding effect on the target side of the sub-pixel light-emitting region, and thus the specific way to provide the first light-shielding member and second light-shielding member is not limited.

It is worth stating that the above description of the specific implementation of the second light-shielding member is only an exemplary demonstration, and other specific realizations are not excluded in practical applications, for which no limitation is made.

It is to be understood that the number of the first light-shielding member, the second light-shielding member, the light-transmitting region, and the sub-pixel light-emitting region, etc. shown in FIG. 8 is only an exemplary demonstration, and there is no limitation on the number in practical applications.

Considering that there may be a difference in a size of the area of each sub-pixel light-emitting region of the light-emitting layer 101, for example, the size of the area of the light-emitting region of different sub-pixel types such as a red sub-pixel, a green sub-pixel, a blue sub-pixel, and the like, may be different, and accordingly, the angle of the emitted light may also differ. To address this problem, as an example, the number and/or thickness of the first light-shielding member corresponding to each sub-pixel light-emitting region of the light-emitting layer 101 may be determined according to the size of the area of each sub-pixel light-emitting region, and by controlling the number and/or thickness of the first light-shielding member corresponding to each sub-pixel light-emitting region, it is possible to control a maximum light emission angle of the sub-pixel light-emitting region, thereby ensuring that the maximum light emission angle of each sub-pixel light-emitting region is close to each other. It is worth noting that the above description of the control method for the maximum light emission angle of the sub-pixel light-emitting regions is only an exemplary demonstration, and other control methods are not ruled out in practical applications, and no limitation is made herein.

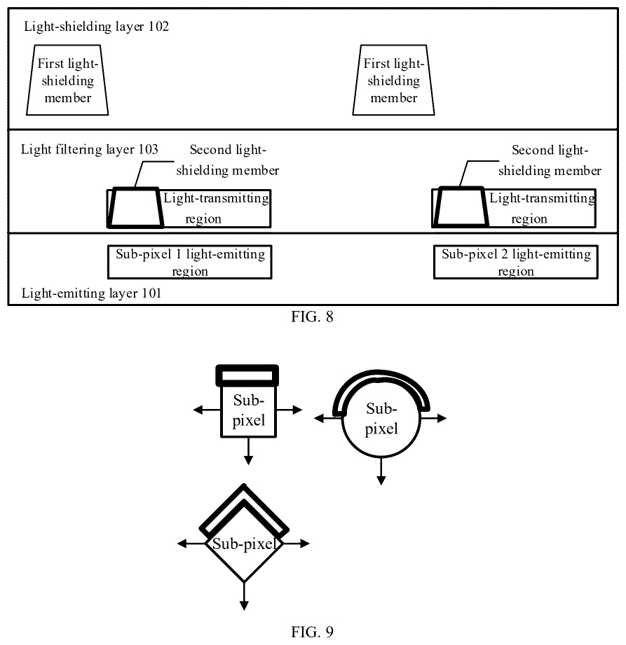

Considering that there may be different shapes of the sub-pixel light-emitting region of the light-emitting layer 101, as an example, for the different edge shapes of the sub-pixel light-emitting region of the light-emitting layer 101, the above-described first light-shielding member may have a shape corresponding to the edge shape of this sub-pixel light-emitting region. As an example, the above-described second light-shielding member may also have a shape corresponding to the edge shape of this sub-pixel light-emitting region. Taking FIG. 9 as an example, the sub-pixel light-emitting region may have various shapes such as a rectangle, a diamond, a circle, and the like as shown in FIG. 9, and then, according to the edge shape of the sub-pixel light-emitting region, the light-shielding member of the corresponding shape may be arranged on the above-described target side of the sub-pixel light-emitting region.

The sub-pixel corresponding to the above sub-pixel light-emitting region may have a variety of types, and as an example, the type of the sub-pixel may be a red sub-pixel, a blue sub-pixel, a green sub-pixel, and the sub-pixel may be of other types, which is not limited specifically.

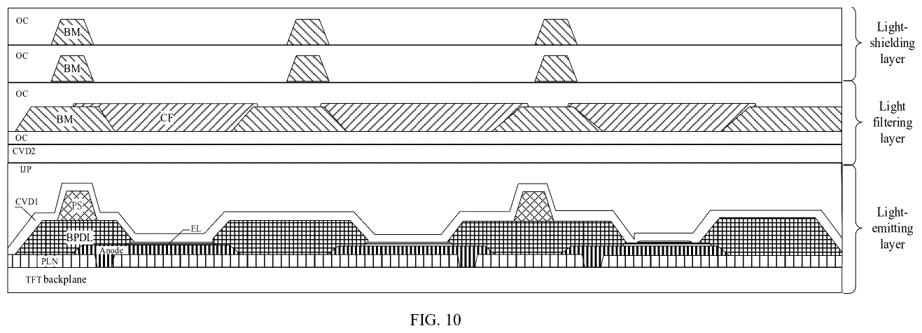

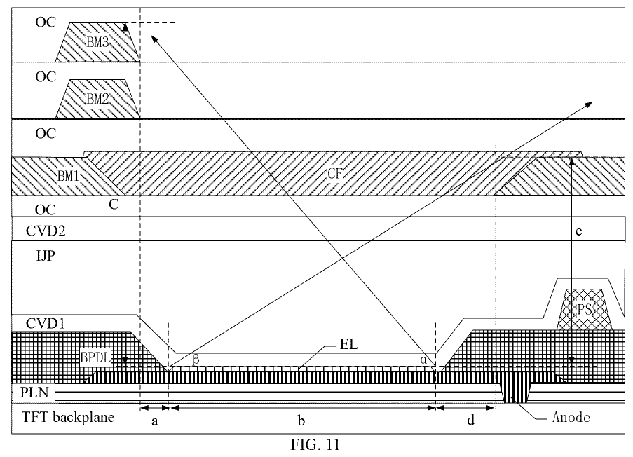

Referring to FIGS. 10 to 12, the following exemplary application scenarios of a display device of an embodiment of the present application are described below.

Taking the display device applied in the vehicle scenario as an example, the display device can be an Organic Light-Emitting Diode (Oled) screen, as shown in FIG. 10, the Oled screen of this embodiment can be divided into the light-emitting layer, the light filtering layer, and the light-shielding layer. The light-emitting layer can at least include a thin-film Transistor (TFT) backplane, an Anode, a Black Pixel Definition Layer (BPDL), an Emissive Layer (EL) (i.e., the sub-pixel light-emitting region described in any of the above embodiments), a PLN for encapsulation and flattening, a Chemical Vapor Deposition (CVD) (e.g., CVD1, CVD2 shown in FIG. 10), Ink Jet Printing (IJP), and over coat (OC). The light filtering layer includes at least a light filtering Color filter On Encapsulation (COE) structure, which includes BM and CF (i.e., the light-transmitting region described in any of the embodiments above), and the light filtering layer may also include an OC for encapsulation and flattening. The light-shielding layer may include several layers of BM layers (i.e., a first light-shielding member described in any of the embodiments above), and an OC for encapsulation and flattening.

As shown in FIG. 11, as an example, the sub-pixel light-emitting region corresponds to two first light-shielding members (BM2, BM3), BM1 may be a BM located outside the light-transmitting region CF in the above-described COE structure, and BM2, as well as BM3, may be two layers of BM in the light-shielding layer (as the first light-shielding members), where a distance between boundaries of BM2 and BM3 and a boundary of the sub-pixel light-emitting region, is less than a distance between a boundary of BM1 and the boundary of the sub-pixel light-emitting region. For example, ‘a’ may be a distance between the right boundary of BM2 or BM3 and the left boundary of the sub-pixel light-emitting region, ‘b’ may be a distance between the left and right boundaries of the sub-pixel light-emitting region, ‘c’ may be a difference in height between the BM3 of the highest layer and the sub-pixel light-emitting region (e.g., EL), ‘d’ may be a distance between the right boundary of the sub-pixel light-emitting region and the left boundary of BM1, and ‘e’ may be a difference in height between BM1 and the sub-pixel light-emitting region. As shown in FIG. 11, ‘a’ is less than ‘d’. Take angles at which light is emitted from left and right endpoints of the sub-pixel light-emitting region as an example, a, B:

$$α = arctan \{ \frac{c}{a + b} \} \qquad ( 1 )$$

$$β = arctan \{ e / ( b + d ) \} \qquad ( 2 )$$

Then the maximum angle of light emitted from the sub-pixel light-emitting region with respect to a line vertical to the sub-pixel light-emitting region and towards the BM3 side may be:

90°−arctan {c/(a+b)} (3)

The maximum angle of light emitted from the sub-pixel light-emitting region with respect to a line vertical to the sub-pixel light-emitting region and towards the side away from BM3 may be:

90°−arctan{e/(b+d)} (4)

As can be seen from the above equations of the light emission angles of the left and right endpoints of the sub-pixel light-emitting region, the maximum emission angle on the BM3 side is much smaller than the maximum emission angle on the side away from BM3.

From the figure, it can be seen that as the value of ‘c’ becomes larger, the value of ‘a+b’ becomes smaller, and the maximum emission angle of the BM3 side becomes smaller. Based on this, the maximum emission angle of the BM3 side can be adjusted.

For the size of ‘b’, generally, it can take 15-35 um; for the value of ‘a’, it can take a value greater than or equal to 0 to ensure the light emission efficiency of the sub-pixel light-emitting region in the direction perpendicular to the display panel; the width of BM2 or BM3 can be greater than or equal to (d+2) um, and ‘d’ generally takes 4 um to avoid the light emitted by the sub-pixel light-emitting region through a slit between BM1 and BM2.

The size of ‘c’ generally takes 35 um, ‘c’ can be increased by increasing the number of BMs in the light-shielding layer, for example, by stacking BM4 and BM5 in addition to BM2 and BM3; in order to increase the size of ‘c’, it is also possible to arrange the BM2 and BM3 above the FMLOC process, and to design a metal pattern used for touch control under the BM2 or the BM3 in order to cushion the BM2 or the BM3 so as to increase a value of ‘c’.

It is assumed that ‘c’=40 um, ‘a’=0 um, ‘b’=25 um, ‘d’=4 um, and ‘e’=20 um, the maximum emission angle of the sub-pixel light-emitting region on the BM3 side is 32°, and the maximum emission angle on the side away from BM3 is 55°.

Since there is a difference in the size of the area of the sub-pixel light-emitting region, i.e., there is a difference in the size of ‘b’, the value of ‘a’ can be adjusted to ensure that the sizes of ‘a+b’ of different sub-pixel light-emitting regions are close, i.e., the maximum emission angles are close; and the number of stacked BMs, i.e., the value of ‘c’, can be adjusted to ensure that the maximum emission angles of each sub-pixel light-emitting region are close. For example, as the area of the sub-pixel light-emitting region becomes larger, the more layers of BMs can be stacked (one more layer of BMs will increase ‘c’ by about 5 um).

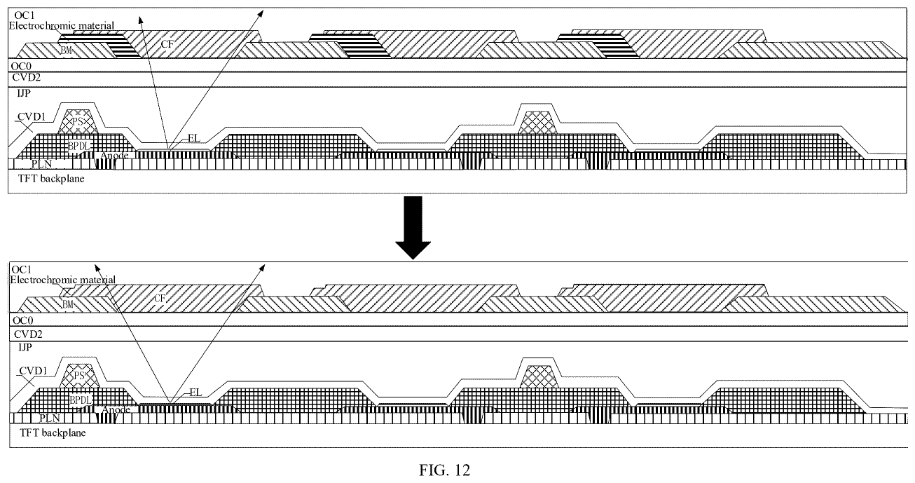

As shown in FIG. 12, the electrochromic material can be fixed around the BM of the light filtering layer and in the light-transmitting region (CF); when no voltage is applied to the electrochromic material during driving, the electrochromic material behaves as a black color, and when a different voltage is applied to the electrochromic material during parking of the vehicle, the electrochromic material can be adjusted to the color corresponding to the sub-pixel color. For example, electrodes are provided on upper and lower sides of the electrochromic material, and by applying different voltages to the two electrodes, a voltage difference is formed, so that the electrochromic material can be adjusted to a color corresponding to the sub-pixel color.

In some embodiments, as shown in FIG. 12, the electrochromic material may be disposed between the Black Matrix and the CF, and at least a portion of the electrochromic material covers the surface of the Black Matrix and at least a portion of the electrochromic material is disposed in the light-transmitting region (CF). For example, a positive projection of the electrochromic material on a TFT backplane at least partially overlaps a positive projection of a spacer PS on the TFT backplane, and at least a portion of the positive projection of the electrochromic material on the TFT backplane partially overlaps a positive projection of an anode on the TFT backplane.

The technical solution provided by embodiments of the present application is capable of providing a light-shielding member on one side of the sub-pixel light-emitting region in the display device as needed to shield the large-angle light emitted from the sub-pixel light-emitting region on that side to avoid affecting the driver's line of sight, and at the same time to ensure that the light emitted from the sub-pixel light-emitting region on the other side is normal, so as to minimize affecting the overall display brightness of the display device.

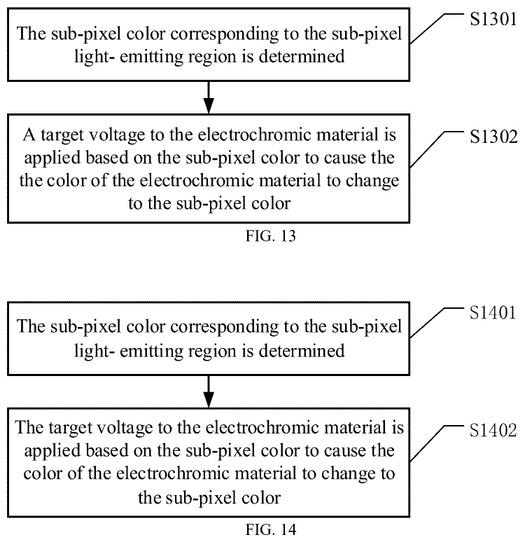

Corresponding to the display device described in any one of the embodiments above, one embodiment of the present application further provides a display method, applied to the display device described in any one of the embodiments above, where the first light-shielding member is the electrochromic material, and where the electrochromic material is capable of changing to a different color when being applied with different voltages as shown in FIG. 13, where the method includes the following steps.

S1301, the sub-pixel color corresponding to the sub-pixel light-emitting region is determined.

S1302, a target voltage to the electrochromic material is applied based on a sub-pixel color to cause the color of the electrochromic material to change to the sub-pixel color.

It will be appreciated that the target voltage corresponds to the sub-pixel color, and the electrochromic material is capable of changing to different colors when different target voltages are applied.

As an example, if the above-described display device is applied to the vehicle driving scenario, as an example, if the vehicle is detected to be in a driving state, no voltage may be applied to the electrochromic material, at which time the electrochromic material may be represented as black; if the vehicle is detected to be in a parked state, the above-described target voltage may be applied to the electrochromic material to cause a color change of the electrochromic material to the color of the above-described sub-pixel color.

Corresponding to the display device described in any of the embodiments above, another embodiment of the present application further provides a display method, applied to the display device described in any of the embodiments above, where the first light-shielding member and/or the second light-shielding member is the electrochromic material, as shown in FIG. 14, the method including the following steps.

S1401, the sub-pixel color corresponding to the sub-pixel light-emitting region is determined.

S1402, the target voltage to the electrochromic material is applied based on the sub-pixel color to cause the color of the electrochromic material to change to the sub-pixel color.

It will be appreciated that the target voltage corresponds to the sub-pixel color, and the electrochromic material is capable of changing to a different colors when different target voltages are applied.

As an example, if the above-described display device is applied to the vehicle driving scenario, as an example, if the vehicle is detected to be in the driving state, no voltage may be applied to the electrochromic material, at which time the electrochromic material may be represented as black; if the vehicle is detected to be in the parked state, the above-described target voltage may be applied to the electrochromic material to cause a color change of the electrochromic material to the color of the above-described sub-pixel color.

The foregoing are only specific embodiments of the present application, and it should be noted that for a person of ordinary skill in the art, a number of improvements and embellishments may be made without departing from the principles of the present application, and these improvements and embellishments shall also be regarded as the scope of protection of the present application.

1. A display device comprising: a light-emitting layer and a light-shielding layer, the light-emitting layer being disposed opposite the light-shielding layer;
wherein the light-emitting layer comprises a number of sub-pixel light-emitting regions, and the light-shielding layer comprises a number of first light-shielding members; each of the sub-pixel light-emitting regions corresponds to at least one first light-shielding member, wherein the first light-shielding members corresponding to each of the sub-pixel light-emitting regions are disposed around a target side of the sub-pixel light-emitting region to shield light emitted from the sub-pixel light-emitting region on the target side.

2. The display device according to claim 1, wherein the display device is applied to a vehicle driving scenario, and the display device comprises at least a main driver display region;
within the main driver display region, the target side comprises a side of the sub-pixel light-emitting region near a vehicle windshield.

3. The display device according to claim 1, wherein the display device is applied to a vehicle driving scenario, and the display device comprises at least a front-seat passenger display region;
within the front-seat passenger display region, the target side comprises a side of the sub-pixel light-emitting region near a vehicle windshield, and/or, the target side comprises a side of the sub-pixel light-emitting region near a main driver's seat.

4. The display device according to claim 1, wherein the display device is applied to a vehicle driving scenario, and the display device comprises at least a center control display region;
within the center control display region, the target side comprises a side of the sub-pixel light-emitting region near a vehicle windshield.

5. The display device according to claim 1, wherein the display device is applied to a vehicle driving scenario, and the display device integrates a main driver display region, a front-seat passenger display region, and a center control display region;
within the main driver display region, the target side comprises a side of the sub-pixel light-emitting region near a vehicle windshield;
within the front-seat passenger display region, the target side comprises a side of the sub-pixel light-emitting region near the vehicle windshield, and/or, the target side comprises a side of the sub-pixel light-emitting region near a main driver's seat; and
within the center control display region, the target side comprises the side of the sub-pixel light-emitting region near the vehicle windshield.

6. The display device according to claim 1, wherein the first light-shielding member is an electrochromic material, the electrochromic material being capable of changing to different colors when different voltages are applied.

7. The display device according to claim 6, wherein the electrochromic material is capable of changing to black when no voltage is applied; and the electrochromic material is capable of changing to a same color as a sub-pixel color when a target voltage is applied.

8. The display device according to claim 1, wherein the first light-shielding member is Black Matrix.

9. The display device according to claim 1, wherein the display device further comprises a light filtering layer, the light filtering layer being disposed between the light-emitting layer as well as the light-shielding layer, and for cooperating with the light-emitting layer to absorb ambient light emitted into the display device.

10. The display device according to claim 9, wherein the light filtering layer comprises a Color filter On Encapsulation (COE) structure.

11. The display device according to claim 9, wherein the light filtering layer comprises a number of light-transmitting regions and a number of second light-shielding members;
each of the sub-pixel light-emitting regions corresponds to one of the light-transmitting regions, the light-transmitting region being used for transmitting light emitted from the sub-pixel light-emitting region;
the second light-shielding member is an electrochromic material, the electrochromic material being capable of changing to different colors when different voltages are applied; the second light-shielding member is disposed in the light-transmitting region and around the target side.

12. The display device according to claim 1, wherein a number and/or thickness of the first light-shielding members corresponding to each of the sub-pixel light-emitting regions is determined according to a size of an area of the sub-pixel light-emitting region.

13. The display device according to claim 1, wherein a shape of the first light-shielding member corresponds to an edge shape of the corresponding sub-pixel light-emitting region.

14. A display method, applied to the display device of claim 1, the first light-shielding member is an electrochromic material, the electrochromic material being capable of changing to different colors when different voltages are applied, the method comprising:
determining a sub-pixel color corresponding to the sub-pixel light-emitting region; and
applying a target voltage to the electrochromic material based on the sub-pixel color to cause a color of the electrochromic material to change to the sub-pixel color.

15. A display method, applied to the display device of claim 11, wherein the first light-shielding member and/or the second light-shielding member is the electrochromic material, the method comprising:
determining a sub-pixel color corresponding to the sub-pixel light-emitting region; and
applying a target voltage to the electrochromic material based on the sub-pixel color, to cause a color of the electrochromic material to change to the sub-pixel color.
